(19) United States
(12) Patent Application Publication
(10) Pub. No.: US 2025/0107287 A1
(43) Pub. Date: Mar. 27, 2025

(54) COLOR REFLECTIVE DISPLAY PANEL

(71) Applicant: E Ink Holdings Inc., Hsinchu (TW)

(72) Inventors: Jau-Min Ding, Hsinchu (TW); Po-Yuan Lo, Hsinchu (TW); Ian French, Hsinchu (TW)

(73) Assignee: E Ink Holdings Inc., Hsinchu (TW)

(21) Appl. No.: 18/751,355

(22) Filed: Jun. 24, 2024

(30) Foreign Application Priority Data
Sep. 25, 2023 (TW) 112136522

(51) Int. Cl. H01L 33/50; H01L 25/075

(52) U.S. Cl. CPC H10H 20/851; H01L 25/0753

(57) ABSTRACT

A color reflective display panel including a reflective display panel and a color filter array is provided. The color filter array is disposed on the reflective display panel. The color filter array includes a plurality of pixel units. Each pixel unit includes one or more first pixels having a first color, one or more second pixels having a second color, and one or more third pixels having a third color. The ratio of the area of the third pixels to the area of the pixel unit is less than one-third.

### CROSS-REFERENCE TO RELATED APPLICATION

This application claims the priority benefit of Taiwan application serial no. 112136522, filed on Sep. 25, 2023. The entirety of the above-mentioned patent application is hereby incorporated by reference herein and made a part of this specification.

### BACKGROUND

### Technical Field

The disclosure relates to a display panel, and in particular to a color reflective display panel.

### Description of Related Art

In general, a color reflective display requires a color filter array (CFA) to display colors. The color filter array generally comprises three primary colors, red, green, and blue, occupying equal areas. This is beneficial to emissive displays such as liquid crystal displays, organic light-emitting diodes, and picture tubes. Compared with the emissive displays, reflective displays usually look darker due to having no light source. In addition, the performance of the reflective displays also depends on the surrounding lighting conditions, which likely leads to the difficulty of displaying bright colors, such as yellow.

### SUMMARY

The disclosure provides a color reflective display panel, and a color filter array thereof can increase the area of a region of red and a region of green and reduce the area of a region of blue according to an arrangement manner of the regions of color, so that the displayed red, green, and yellow can be brighter, and the blue can be darker.

The color reflective display panel of the disclosure includes a reflective display panel and a color filter array. The color filter array is disposed on the reflective display panel. The color filter array includes a plurality of pixel units. Each pixel unit includes a plurality of first pixels having a first color, a plurality of second pixels having a second color, and a plurality of third pixels having a third color. A ratio of an area of the third pixels to an area of the pixel unit is less than one-third.

In an embodiment of the disclosure, a ratio of an area of the first pixels to an area of the pixel unit is greater than one-third, and a ratio of an area of the second pixels to the area of the pixel unit is greater than one-third.

In an embodiment of the disclosure, a ratio of an area of the third pixels to an area of the pixel unit is 20%±5%.

In an embodiment of the disclosure, a ratio of an area of the third pixels to an area of the pixel unit is 20%.

In an embodiment of the disclosure, a pixel fill factor (CFA) of the first color is pFF1, a pixel fill factor of second color is pFF2, a pixel fill factor of third color is pFF3, and pFF1, pFF2 and pFF3 comply with the condition of pFF1:pFF2:pFF3=1:1:2.

In an embodiment of the disclosure, a ratio of an area of the third pixels to an area of the pixel unit is 25%.

In an embodiment of the disclosure, a pixel fill factor of the first color is pFF1, a pixel fill factor of second color is pFF2, a pixel fill factor of third color is pFF3, and pFF1, pFF2, and pFF3 comply with the condition of pFF1:pFF2:pFF3=2:2:3.

In an embodiment of the disclosure, the above-mentioned first color is red, the second color is green, and the third color is blue.

In an embodiment of the disclosure, the shapes of a region of the first color and a region of the second color are different from the shape of a region of the third color.

In an embodiment of the disclosure, the shapes of a region of the first color and a region of the second color are the same as the shape of a region of the third color.

In order to make the above-mentioned features and advantages of the disclosure more comprehensible, the embodiments are described in detail below with the accompanying drawings.

### BRIEF DESCRIPTION OF THE DRAWINGS

FIG. 1 is a schematic diagram of a color reflective display panel according to an embodiment of the disclosure.

FIG. 2 is a schematic diagram of a color filter array according to the embodiment in FIG. 1 of the disclosure.

FIG. 3 is a schematic diagram of a pixel unit according to another embodiment of the disclosure.

FIG. 4 is a schematic diagram of a color filter array according to another embodiment of the disclosure.

FIG. 5 is a schematic diagram of a color filter array according to another embodiment of the disclosure.

FIG. 6 is a schematic diagram of a color filter array according to another embodiment of the disclosure.

### DESCRIPTION OF THE EMBODIMENTS

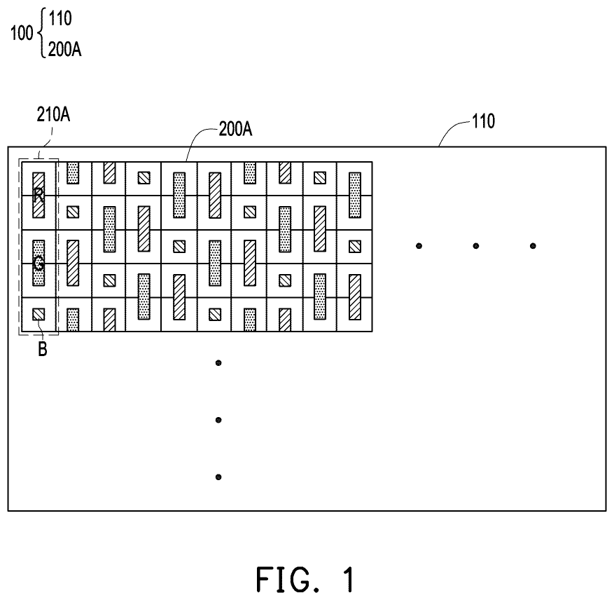

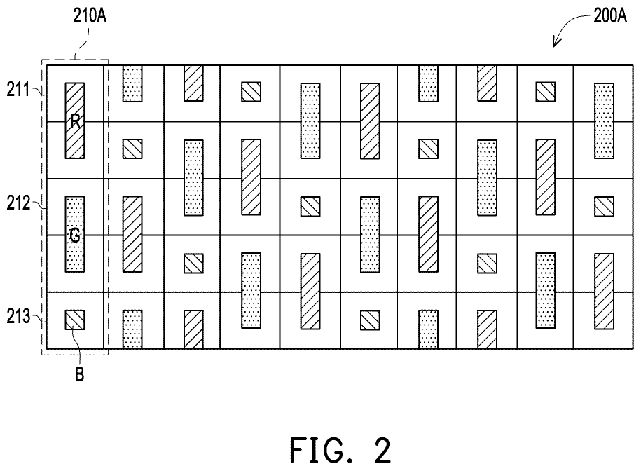

FIG. 1 is a schematic diagram of a color reflective display panel according to an embodiment of the disclosure. FIG. 2 is a schematic diagram of a color filter array according to the embodiment in FIG. 1 of the disclosure. Referring to FIG. 1 and FIG. 2, a color reflective display panel 100 includes a reflective display panel 110 and a color filter array 200A. The color filter array 200A is disposed on the reflective display panel 110. The color filter array 200A includes a plurality of pixel units 210A. The repeated arrangement of the pixel units 210A may form the color filter array 200A.

Specifically, the pixel unit 210A includes two first pixels 211, two second pixels 212, and one third pixel 213. The first pixel 211 has a first color R, the second pixel 212 has a second color G, and the third pixel 213 has a third color B. In this embodiment, the first color R is red, the second color G is green, and the third color B is blue.

In this embodiment, a ratio of an area of the two first pixels 211 to an area of the pixel

unit 210A is 40%, a ratio of an area of the two second pixels 212 to the area of the pixel unit 210A is 40%, and a ratio of an area of the one third pixel 213 to the area of the pixel unit 210A is 20%. That is to say, the ratio of the area of the two first pixels 211 to the area of the pixel unit 210A is greater than one-third, the ratio of the area of the two second pixels 212 to the area of the pixel unit 210A is greater than one-third, and the ratio of the area of the one third pixel 213 to the area of the pixel unit 210A is less than one-third.

On the other hand, a pixel fill factor of the first color R is pFF1, a pixel fill factor of the second color G is pFF2, and a pixel fill factor of the third color B is pFF3. In this embodiment, pFF1, pFF2, and pFF3 comply with the condition of pFF1:pFF2:pFF3=1:1:2 to maintain white balance. pFF1:pFF2:pFF3=1/N1:1/N2:1/N3, N1 is the pixel quantity of the first color R in the pixel unit 210A, N2 is the pixel quantity of the second color G in the pixel unit 210A, and N3 is the pixel quantity of the third color B in the pixel unit 210A.

In addition, the shapes of a region of the first color R and a region of the second color G are formed in a rectangular shape, and the shape of a region of the third color B is formed in a square shape, which are different.

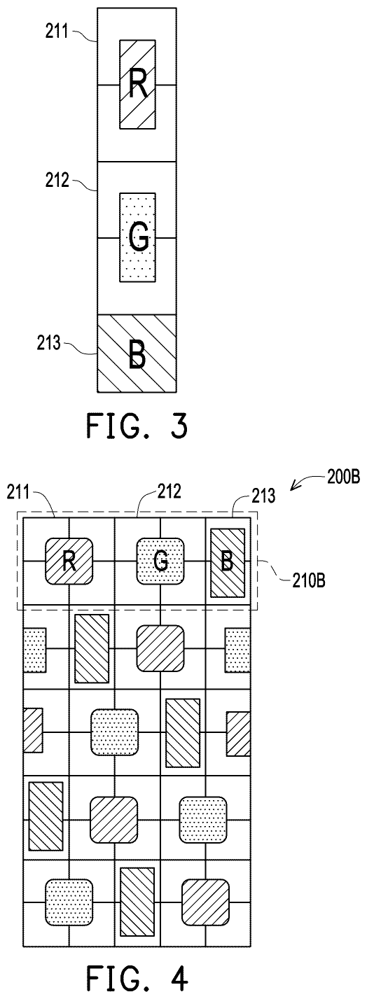

FIG. 3 is a schematic diagram of a pixel unit according to another embodiment of the disclosure. Referring to FIG. 3, in this embodiment, the third color B of the pixel unit 210A may also fill the entire third pixel 213.

FIG. 4 is a schematic diagram of a color filter array according to another embodiment of the disclosure. Referring to FIG. 4, a color filter array 200B includes a plurality of pixel units 210B. The repeated arrangement of the pixel units 210B may form the color filter array 200B.

Specifically, the pixel unit 210B includes four first pixels 211, four second pixels 212, and two third pixels 213. A ratio of an area of the four first pixels 211 to an area of the pixel unit 210B is 40%, a ratio of an area of the four second pixels 212 to the area of the pixel unit 210B is 40%, and a ratio of an area of the two third pixels 213 to the area of the pixel unit 210B is 20%.

On the other hand, in this embodiment, pFF1, pFF2, and pFF3 comply with the condition of pFF1:pFF2:pFF3=1:1:2 to maintain white balance. In addition, the shapes of the region of the first color R and the region of the second color G are formed in a rectangular shape, and the shape of the region of the third color B is formed in a square shape, which are different.

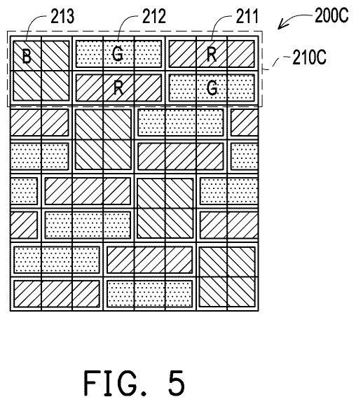

FIG. 5 is a schematic diagram of a color filter array according to another embodiment of the disclosure. Referring to FIG. 5, a color filter array 200C includes a plurality of pixel units 210C. The repeated arrangement of the pixel units 210C may form the color filter array 200C.

Specifically, the pixel unit 210C includes six first pixels 211, six second pixels 212, and four third pixels 213. A ratio of an area of the six first pixels 211 to an area of the pixel unit 210C is 37.5%, a ratio of an area of the six second pixels 212 to the area of the pixel unit 210C is 37.5%, and a ratio of an area of the four third pixels 213 to the area of the pixel unit 210C is 25%. That is to say, in the embodiment of the disclosure, the ratio of the area of the third pixels to the area of the pixel unit may be 20%±5%, that is, in a range of 15% to 25% (including 15% and 25%).

On the other hand, in this embodiment, pFF1, pFF2, and pFF3 comply with the condition of pFF1:pFF2:pFF3=2:2:3 to maintain white balance. In addition, the shapes of the region of the first color R and the region of the second color G are formed in a rectangular shape, and the shape of the region of the third color B is formed in a square shape, which are different.

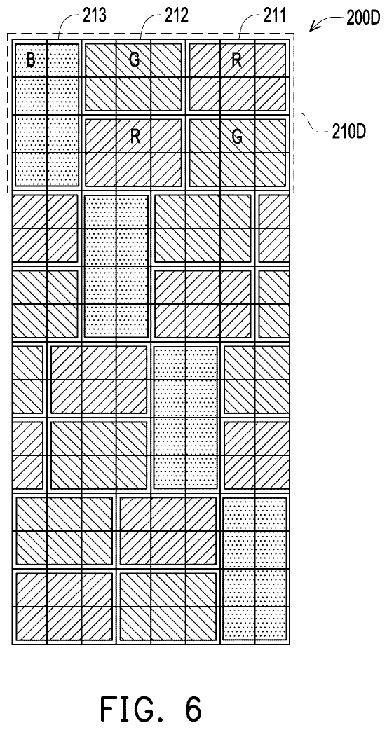

FIG. 6 is a schematic diagram of a color filter array according to another embodiment of the disclosure. Referring to FIG. 6, a color filter array 200D includes a plurality of pixel units 210D. The repeated arrangement of the pixel units 210D may form the color filter array 200D.

Specifically, the pixel unit 210D includes twelve first pixels 211, twelve second pixels 212, and eight third pixels 213. A ratio of an area of the twelve first pixels 211 to an area of the pixel unit 210D is 37.5%, a ratio of an area of the twelve second pixels 212 to the area of the pixel unit 210D is 37.5%, and a ratio of an area of the eight third pixels 213 to the area of the pixel unit 210D is 25%.

On the other hand, in this embodiment, pFF1, pFF2, and pFF3 comply with the condition of pFF1:pFF2:pFF3=2:2:3 to maintain white balance. In addition, the shapes of the region of the first color R, the region of the second color G, and the region of the third color B are the same and formed in a rectangular shape.

In summary, in the embodiment of the disclosure, the color filter array can increase the area of the region of red and the region of green in the pixel unit and reduce the area of the region of blue according to the arrangement manner of the regions of color, so that the displayed red, green, and yellow can be brighter, and the blue can be darker.

Although the disclosure has been disclosed above in the embodiments, the embodiments are not intended to limit the disclosure. Persons with ordinary knowledge in the technical field can make some changes and modifications without departing from the spirit and scope of the disclosure. Therefore, the protection scope of the disclosure shall be determined by the appended claims.

What is claimed is:

1. A color reflective display panel, comprising:
a reflective display panel; and
a color filter array disposed on the reflective display panel, wherein the color filter array comprises a plurality of pixel units, each of the plurality of pixel units comprises one or more first pixels having a first color, one or more second pixels having a second color, and one or more third pixels having a third color,
wherein a ratio of an area of the one or more third pixels to an area of the pixel unit is less than one-third.

2. The color reflective display panel as claimed in claim 1, wherein a ratio of an area of the one or more first pixels to the area of the pixel unit is greater than one-third, and a ratio of an area of the one or more second pixels to the area of the pixel unit is greater than one-third.

3. The color reflective display panel as claimed in claim 1, wherein the ratio of the area of the one or more third pixels to the area of the pixel unit is 20%±5%.

4. The color reflective display panel as claimed in claim 3, wherein the ratio of the area of the one or more third pixels to the area of the pixel unit is 20%.

5. The color reflective display panel as claimed in claim 4, wherein a pixel fill factor of the first color is pFF1, a pixel fill factor of the second color is pFF2, a pixel fill factor of the third color is pFF3, and pFF1, pFF2, and pFF3 comply with a condition of pFF1:pFF2:pFF3=1:1:2.

6. The color reflective display panel as claimed in claim 3, wherein the ratio of the area of the one or more third pixels to the area of the pixel unit is 25%.

7. The color reflective display panel as claimed in claim 6, wherein a pixel fill factor of the first color is pFF1, a pixel fill factor of the second color is pFF2, a pixel fill factor of the third color is pFF3, and pFF1, pFF2, and pFF3 comply with a condition of pFF1:pFF2:pFF3=2:2:3.

8. The color reflective display panel as claimed in claim 1, wherein the first color is red, the second color is green, and the third color is blue.

9. The color reflective display panel as claimed in claim 1, wherein shapes of a region of the first color and a region of the second color are different from a shape of a region of the third color.

10. The color reflective display panel as claimed in claim 1, wherein shapes of a region of the first color and a region of the second color are the same as a shape of a region of the third color.
